(19) United States
(12) Patent Application Publication
(10) Pub. No.: US 2006/0292780 A1
(43) Pub. Date: Dec. 28, 2006

(54) Field-effect transistor and method for producing a field-effect transistor

(75) Inventor: Mojtaba Joodaki, Muenchen (DE)

Correspondence Address: MCGRATH, GEISSLER, OLDS & RICHARDSON, PLLC, P.O. BOX 1364, FAIRFAX, VA, 22038-1364, US

(73) Assignee: ATMEL Germany GmbH

(21) Appl. No.: 11/473,142

(22) Filed: Jun. 23, 2006

(30) Foreign Application Priority Data
Jun. 25, 2005 (DE) DE10 2005 028 837

(51) Int. Cl. H01L 21/8234; H01L 29/76

(52) U.S. Cl. 438/197; 257/288

(57) ABSTRACT

Field-effect transistor is disclosed that includes a gate oxide, a polycrystalline layer applied on the gate oxide, and at least one spacer of polycrystalline silicon, wherein the gate oxide has a first thickness in a first region beneath the polycrystalline silicon layer and a second thickness in a second region beneath the at least one spacer, and wherein the second thickness of the gate oxide in the second region is reduced as compared to the first thickness of the gate oxide in the first region.

This nonprovisional application claims priority under 35 U.S.C. § 119(a) on German Patent Application No. DE 10 2005 028 837, which was filed in Germany on Jun. 25, 2005, and which is herein incorporated by reference.

### BACKGROUND OF THE INVENTION

1. Field of the Invention

The present invention relates to a field-effect transistor and a method for producing a field-effect transistor.

2. Description of the Background Art

It is disclosed in IEEE Trans. on Electron Devices, Vol. 47, No. 4, April, 2000, in “Device Scaling Effects on Hot-Carrier Induced Interface and Oxide-Trapped Charge Distributions in MOSFETs,” that a maximum of a distribution of so-called hot charge carriers and trapped charges in the gate oxide occurs within 20 nm of the drain PN junction for various gate lengths and thicknesses of the gate oxide. This is analyzed for a MOSFET (Metal Oxide Semiconductor Field-Effect Transistor) with an LDD (Lightly Doped Drain) structure.

An analysis of MOSFETs with an LDD structure is also disclosed in IEEE Trans. on Electron Devices, Vol. 47, No. 1, January, 2000, “MOSFET Channel Length: Extraction and Interpretation,” and in IEEE Trans. on Electron Devices, Vol. 45, No. 6, June, 1998, “A Novel Single-Device DC Method for Extraction of the Effective Mobility and Source-Drain Resistances of Fresh and Hot-Carrier Degraded Drain-Engineered MOSFETs.”

From DE 195 36 523 is known a method for producing a gate electrode in an integrated circuit. In this process a gate oxide is produced on a substrate, and an auxiliary layer is deposited and is structured at the place where the gate electrode is to be produced. A layer of a material that forms the gate electrode is deposited, and a spacer is etched from this layer. Then the auxiliary layer is removed and the spacer is used as a gate electrode. This is supposed to make it possible to produce sublithographic structures. The size of the spacer, and thus of the gate electrode, depends on the variation in thickness of the deposited layer.

The layer used for spacer formation and gate electrode production consists of polysilicon. First, a thin layer of polysilicon with a thickness of approximately 100 nm is applied on the gate oxide. This polysilicon layer serves as an etch stop in the removal of the auxiliary layer, which typically consists of CVD oxide, in order to protect the gate oxide located beneath the polysilicon layer. The use of plasma CVD in deposition or etching mode is particularly preferred, since the method can also be used at low temperatures of approximately 400° C. as a result.

In DE 195 36 523, a gate oxide is produced on a silicon substrate in a preliminary process. In the next step, a thin polysilicon layer of approximately 100 nm is deposited. This layer can be deposited using the plasma CVD process. In the next step, a relatively thick oxide layer with a thickness of approximately 0.5 to 1μm is deposited. This also takes place using the CVD (chemical vapor deposition) process. The oxide layer is photolithographically structured in the next step, wherein in particular the locations are structured where the gate is to be produced. At the edges of the oxide layer thus structured, spacers are produced by conformal deposition of a polysilicon layer and subsequent anisotropic etching.

### SUMMARY OF THE INVENTION

It is therefore an object of the present invention to provide an LDD structure. Accordingly, the object is attained by a field-effect transistor with a gate oxide, a polycrystalline layer applied to the gate oxide, and at least one spacer of polycrystalline silicon.

The gate oxide has a first thickness in the first region beneath the polycrystalline silicon layer. In addition, the gate oxide has a second thickness in a second region beneath the at least one spacer. The second thickness of the gate oxide in the second region is reduced as compared to the first thickness of the gate oxide in the first region.

Here, the first region and the second region are directly adjacent to one another, so that a continuous gate oxide layer with different thickness areas is produced. The gate oxide layer has a smoothed step in the transition region between the first area and the second area. The gate oxide advantageously contains silicon dioxide.

According to an embodiment of the invention, between a highly doped drain semiconductor region with a doping of a first conductivity type and a channel region with a doping of a second conductivity type, there is formed a semiconductor region (LDD) which has a lower doping level than the drain semiconductor region and has a doping of the first conductivity type. In this context, the smoothed step between the first region and the second region of the gate oxide abuts the lower-doped semiconductor region (LDD) in the vicinity of this region. Moreover, a highly doped source semiconductor region can also be provided that is adjacent to an additional semiconductor region having a lower doping level than the source semiconductor region, so that a symmetrical structure of the field-effect transistor is advantageously produced.

According to a further embodiment of the invention, the semiconductor region (LDD) with lower doping than the drain semiconductor region is formed beneath a transition between the first region of the gate oxide and the second region of the gate oxide. The lower-doped semiconductor region advantageously extends at least 10 nm, preferably at least 50 nm, beneath the first region of the gate oxide with the first thickness.

The at least one spacer can be electrically connected by a silicide layer and/or a metal layer. If the spacers are insulated from the gate terminal, they may be connected to a separate, fixed or variable potential. Alternatively, the silicide layer and/or the metal layer of the spacer(s) can be conductively connected to the gate terminal so that the spacers can be connected in a low-resistance manner.

The spacers of polycrystalline silicon may also be made high-resistance, for example, in that they are low doped or intrinsic. If the gate terminal is connected to an additional transistor, a high-resistance design would reduce a capacitive load effect of a gate-oxide capacitance component in the second region of the gate oxide beneath the spacer.

It is of course possible for the silicon layer and the spacers to be conductively connected to one another by a boundary surface, since both the polycrystalline silicon layer and the spacers are conductive. Alternatively hereto, or in combination herewith, that the at least one spacer can be conductively connected, in particular in a low-resistance manner, to the polycrystalline silicon layer through the silicide layer and/or through the metal layer. Moreover, in the case of the ohmic connection through the silicide layer and/or metal layer, it is not necessary to remove an oxide layer, for example native silicon dioxide, arising between the polycrystalline silicon layer and the spacers.

The second thickness of the gate oxide in the second region can be reduced by at least one third as compared to the first thickness of the gate oxide in the first region. Preferably, however, the second thickness is reduced by at least one half as compared to the first thickness of the gate oxide.

Furthermore, the drain-side PN junction can be formed beneath the first region of the gate oxide.

In addition, the object of the invention is attained by a method for manufacturing a field-effect transistor. In this method, a first region of a gate oxide is produced on a semiconductor surface, advantageously a <100>-oriented silicon substrate, through oxidation. A polycrystalline silicon layer can be applied to the gate oxide and structured. Outside of the structured, polycrystalline silicon layer, the exposed gate oxide is removed, in particular by an etching process.

Outside of the structured, polycrystalline silicon layer, a second region of the gate oxide with a thinner oxide thickness than in the first region of the gate oxide is produced, in particular through dry oxidation. In advantageous fashion, the polycrystalline silicon layer acts as a masking for the dry oxidation in the second region. With the dry oxidation, unmasked surfaces of the structured, polycrystalline silicon layer can likewise be oxidized, in particular the side surfaces of this layer. At least one spacer of polycrystalline silicon is produced on the second region of the gate oxide, in particular by the application and etching of polycrystalline silicon.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIGS. 1-5 show schematic cross-sectional views following process steps for the manufacture of a field-effect transistor, according to an embodiment of the present invention.

### DETAILED DESCRIPTION

FIGS. 1-5 show schematic cross-sectional views following process steps for the manufacture of a field-effect transistor. Not all details of the manufacturing process are shown. The majority of these details are standard fabrication processes of an LDD (Lightly Doped Drain) MOSFET.

An essentially finished field-effect transistor is shown in schematic cross-section in FIG. 5. Metallization levels for connecting the terminals (G, D, S) of the field-effect transistor are still lacking, for example. The structure of the field-effect transistor has the terminals gate G, drain D, and source S. The drain terminal D is produced here in that a surface of the drain semiconductor region 81 is silicidized, for example to a TiSi₂ layer 91. The source terminal S is produced here in that a surface of the source semiconductor region 83 is silicidized, for example to a TiSi₂ layer 93.

In this context, the drain semiconductor region 81 and the source semiconductor region have a high dopant concentration with a dopant of a first conductivity type. The semiconductor regions 71 and 73, in contrast, have a significantly lower dopant concentration than the drain semiconductor region 81 and .the source semiconductor region 83. These regions are also called LDD structures, wherein the dopant in the LDD structure has the same conductivity type as the dopant in the drain semiconductor region 81.

A semiconductor region 100 of monocrystalline silicon has the dopant concentration of a substrate or a well, wherein a dopant in the semiconductor region 100 of the substrate or well has a second conductivity type opposite to the first conductivity type. If a voltage greater than a threshold voltage is applied to the gate G, a conductive channel forms there beneath a gate oxide 60 in a channel region 100′ of the substrate 100 of the second conductivity type, so that a flow of current is made possible between the drain terminal D and the source terminal S. Accordingly, the semiconductor region 100 beneath the gate oxide 60 is also called channel region 100′.

Above the gate oxide 60, a polycrystalline silicon layer 40 is formed, which is likewise silicidized for connection. Two spacers 51 and 53 of polycrystalline silicon are formed laterally adjacent to this polycrystalline silicon layer 40. These spacers are likewise silicidized for connection. In this regard, the spacers 51, 53 can be connected in an electrically conductive manner to the polycrystalline silicon layer 40 through the silicide layer 92.

The gate oxide 60 has a first region 62, in which the gate oxide 60 has a first thickness. The gate oxide 60′, 60″ has a second region 61, 63, in which the gate oxide 60′, 60″ has a second thickness. The second thickness is reduced as compared to the first thickness. The reduction in thickness is advantageously more than a third, preferably more than half, the first thickness of the gate oxide 60. The gate oxide 60, 60′, 60″ is made of silicon dioxide. In this context, the gate oxide 60, 60′, 60″ is formed in a single piece.

The polycrystalline silicon layer 40 is formed above the first region 62 with the first thickness of the gate oxide 60. In contrast, the polycrystalline spacers 51, 53 are formed above the second region 61, 63 with the second thickness of the gate oxide 60′, 60″. In the example embodiment shown, the gate oxide 60′, 60″ is formed over the spacers 51, 53 and beyond, to the silicide layer 91, 93.

The lower doped LDD region 71 has a first semiconductor region 711 beneath the spacer 51, and thus beneath the second region 61 of the gate oxide 60″. A second semiconductor region 712 of the LDD region 71 is formed beneath the polycrystalline silicon layer 40, and thus beneath the first region 62 of the gate oxide 60. In analogous fashion, the lower doped LDD region 73 has a first semiconductor region 733 beneath the spacer 53, and thus beneath the second region 63 of the gate oxide 60″. A second semiconductor region 732 of the LDD region 73 is formed beneath the polycrystalline silicon layer 40, and thus beneath the first region 62 of the gate oxide 60. Accordingly, the PN transitions in the channel region are formed beneath the first region 62 of the gate oxide 60.

A length of the polycrystalline silicon layer 40 of the field-effect transistor of the example embodiment shown in FIG. 5 is 0.25 μm. The dopant concentration in the LDD region 71, 73 is 1e18 cm⁻³. The dopant concentration in the channel region is 1e17 cm⁻³. The dopant concentration in the drain semiconductor region 81, in the source semiconductor region 83, and in the polycrystalline gate silicon layer 40 is 1e20 cm⁻³. The dopant concentration in the spacers can correspond to that in the polycrystalline gate silicon layer 40, for example, or, advantageously, can be 1e16 cm⁻³ or less for a high-resistance design of the spacer regions 51, 53.

The LDD region 71, 73 is laterally diffused on both sides 50 nm beneath the first region 62 of the gate oxide 60, and thus approximately 50 nm beneath the polycrystalline silicon layer 40. The gate length here is 0.15 μm. The width of the polycrystalline spacers 53, 51 is 75 nm. The first thickness of the gate oxide 60 beneath the polycrystalline silicon layer 40 is 16 nm, the second thickness of the gate oxide 60′, 60″ below the polycrystalline spacers 51, 53 is 8 nm. With these specifications, the field-effect transistor from FIG. 5 has improved reliability and an improved breakdown voltage as compared to a field-effect transistor with spacers of dielectric. The turn-on resistance and the transconductance are significantly improved, as well. This is achieved in that the potential applied to the spacers 51, 53 causes an enrichment of charge carriers directly beneath the gate oxide 60′, 60″.

FIGS. 1 through 5 also show schematic cross-sectional views of states of the field-effect transistor during the manufacturing process. In this connection, only the most important process steps are mentioned below. For example, cleaning processes, and the application and removal of masking using photoresist, are omitted to make for a simplified presentation.

In process steps, a gate oxide 60 of a first thickness is produced through dry oxidation on an advantageously monocrystalline substrate 100. Then a layer 40 of polycrystalline silicon is applied, and structured by masking. This process state is shown schematically in FIG. 1.

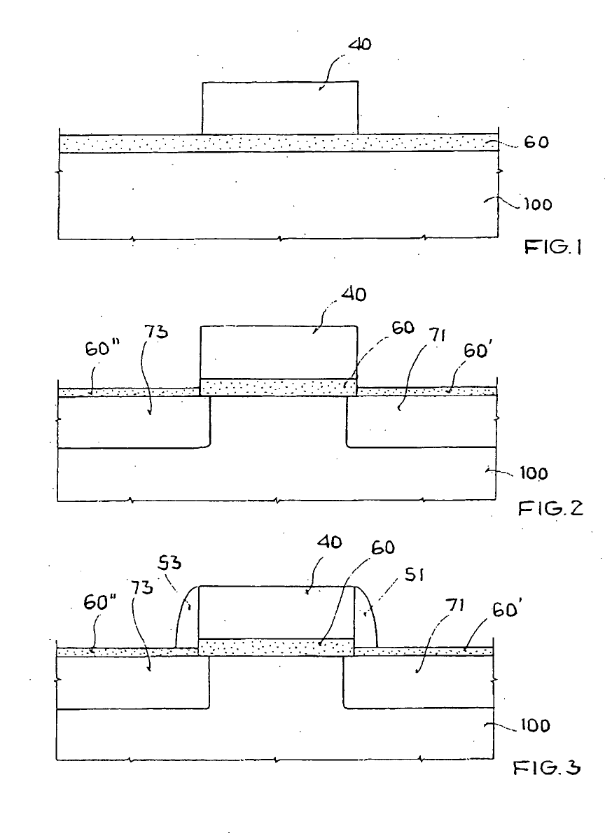

In subsequent steps, the gate oxide 60 outside of a region covered by the structured, polycrystalline silicon layer 40 is removed in that, for example, an etchant that acts selectively with respect to the gate oxide 60 is used. This is followed by renewed dry oxidation of the substrate 100. This repeated dry oxidation produces the gate oxide 60′, 60″ with a reduced thickness outside of the polycrystalline silicon layer 40. In addition, a dopant is introduced, preferably implanted, into the substrate 100 masked by the polycrystalline silicon layer 40. In this regard, the implantation can take place either before or after the formation of the gate oxide 60′, 60″ with the reduced thickness. The dopant for the LDD structures 71, 73 is introduced with this implantation. The resultant process state is shown in FIG. 2.

As an alternative to renewed dry oxidation of the substrate 100, the existing gate oxide 60 can also be partially etched away outside of the covering by the polycrystalline silicon layer 40. To this end, HF or another wet etchant is used, for example. In this connection, the etching is done on a time basis, for example.

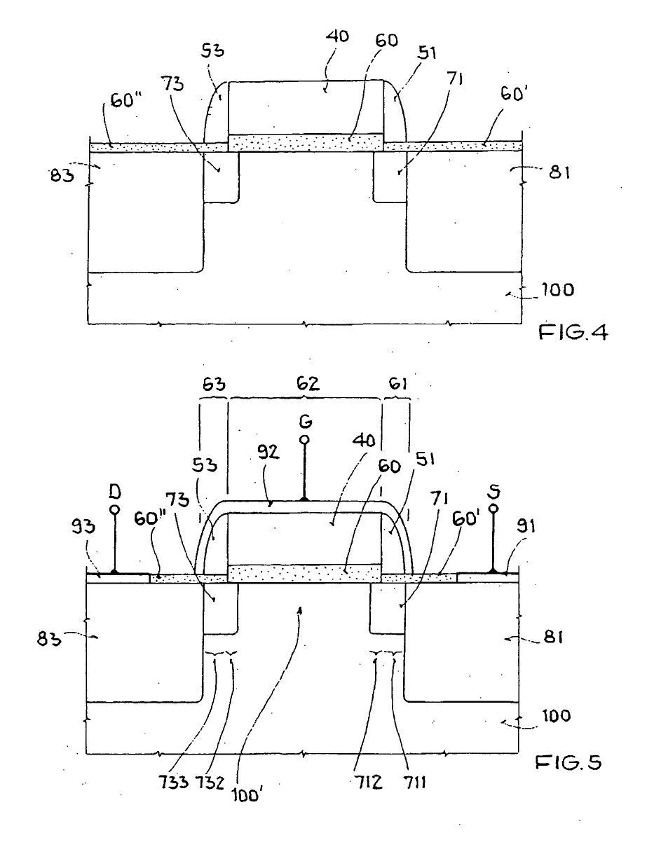

In FIG. 3, spacers 51, 53 of polycrystalline silicon are formed at the edges of the polycrystalline silicon layer 40. After this, as shown in FIG. 4, a dopant is implanted at a high dose in the source semiconductor region 83, in the drain semiconductor region 81, and in the polycrystalline silicon layer 40. If there is no masking on the spacers 51, 53, a high dose of the dopant is also implanted in the spacers 51, 53. If this is not desired, for example, if it is desirable to make high-resistance spacers, then masking is necessary, for instance masking with silicon nitride, which can be applied to the spacers 51, 53 at the end of the manufacturing process.

As shown in FIG. 5, the surfaces of the source semiconductor region 83 and drain semiconductor region 81 are then exposed, and the wafer is coated with a metal layer. In a subsequent silicidizing process, the boundary surfaces between silicon and the adjacent metal are silicidized into one ore more silicide layers 91, 92, 93.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A field-effect transistor comprising:
a gate oxide;
a polycrystalline layer applied to the gate oxide; and
at least one spacer formed of a polycrystalline silicon;
wherein the gate oxide has a first thickness in a first region beneath the polycrystalline silicon layer and a second thickness in a second region beneath the at least one spacer, and
wherein the second thickness of the gate oxide in the second region is reduced as compared to the first thickness of the gate oxide in the first region.

2. The field-effect transistor according to claim 1, wherein between a highly doped drain semiconductor region with a doping of a first conductivity type and a channel region with a doping of a second conductivity type there is formed a semiconductor region which has a lower doping level than the drain semiconductor region and has a doping of the first conductivity type.

3. The field-effect transistor according to claim 2, wherein the semiconductor region with lower doping than the drain semiconductor region is formed beneath a transition between the first region and the second region.

4. The field-effect transistor according to claim 1, wherein the at least one spacer is electrically connected by a silicide layer and/or a metal layer.

5. The field-effect transistor according to claim 1, wherein the at least one spacer is conductively connected to the polycrystalline silicon layer through a silicide layer and/or a metal layer.

6. The field-effect transistor according to claim 1, wherein the second thickness is reduced by at least one third or by at least one half as compared to the first thickness.

7. The field-effect transistor according to claim 1, wherein a drain-side PN junction is formed beneath the first region of the gate oxide.

8. A method for producing a field-effect transistor, the method comprising the steps of:
Producing a first region of a gate oxide on a semiconductor surface through oxidation;
applying and structuring a polycrystalline silicon layer to the gate oxide;
removing an exposed gate oxide outside of the structured, polycrystalline silicon layer;
producing, outside of the structured polycrystalline silicon layer, a second region of the gate oxide with a thinner oxide thickness than in the first region of the gate oxide ; and
forming at least one spacer of polycrystalline silicon on the second region of the gate oxide.
